(19) United States
(12) Patent Application Publication
(10) Pub. No.: US 2017/0154816 A1
(43) Pub. Date: Jun. 1, 2017

(54) AMORPHOUS METAL INTERCONNECTIONS BY SUBTRACTIVE ETCH

(71) Applicant: GLOBALFOUNDRIES Inc., Grand Cayman (KY)

(72) Inventors: Sean X. LIN, Watervliet, NY (US); Ming HE, Menands, NY (US); Frank SMITH, Ballston Lake, NY (US); Xunyuan ZHANG, Albany, NY (US)

(73) Assignee: GLOBALFOUNDRIES Inc., Grand Cayman (KY)

(21) Appl. No.: 14/954,112

(22) Filed: Nov. 30, 2015

(51) Int. Cl. H01L 21/768; H01L 23/532; H01L 23/528; H01L 21/3205; H01L 21/3213

(52) U.S. Cl. CPC H01L 21/76885; H01L 21/76837; H01L 21/7682; H01L 21/32051; H01L 21/32133; H01L 23/528; H01L 21/76892; H01L 23/53209; H01L 23/53261

(57) ABSTRACT

A method of fabricating amorphous metal interconnections includes forming an amorphous metal layer over a base insulating layer on a semiconductor device using an amorphous metal having a non-crystalline structure. A portion of the amorphous metal layer is selectively removed to form a three dimensional pattern within a remaining portion of the amorphous metal layer. A fill insulating layer is disposed over the remaining portion of the amorphous metal layer and base insulating layer to fill the three dimensional pattern to form amorphous metal interconnects between semiconductor devices.

### TECHNICAL FIELD

The present invention relates to semiconductor devices and methods of fabricating the same. More specifically, the invention relates to various methods of forming amorphous metal interconnections between semiconductor devices in an integrated circuit.

### BACKGROUND

With increasing down-scaling of integrated circuits and the increasingly demanding requirements to the speed of integrated circuits, semiconductor devices, such as transistors, need higher drive currents with increasingly smaller dimensions. Copper has a higher electric conductivity and a significantly greater resistance to electro-migration (EM) than aluminum. As a result, copper interconnections have substantially replaced aluminum for smaller semiconductor circuits. The conventional process of manufacturing such copper interconnections involves patterning an underlying insulating layer with openings such as trenches and via. As used herein, an insulating layer shall mean a layer of high resistivity material used to electrically separate and isolate conducting materials. By way of example, an insulating layer may include an interlayer dielectric (ILD) layer (such as a silicon oxide layer) used to separate two metal layers, wherein the ILD layer could be several or many layers above the silicon substrate layer.

Additionally an insulating layer may include an NBLok layer (such as a silicon nitride layer or silicon carbon nitride layer) disposed on a substrate layer. A thick coating of copper that significantly overfills the pattern is then deposited on the insulating layer through processes such as copper platting after PVD barrier and seed deposition. The copper that extends above the top of the insulating layer (known as the overburden) is then removed through various processes, such as chemical-mechanical planarization (CMP). The copper disposed within the openings (e.g., the trenches and via) then becomes the patterned conducting interconnections.

However, below the ten nanometer class of semiconductor fabrication, copper fabrication becomes increasingly problematic. For example, the resistance associated with the copper interconnections increase dramatically. Additionally, a barrier metal layer must completely surround all copper interconnections, since diffusion of copper into the surrounding dielectric (or insulation) would degrade its properties. However the barrier layer within the trenches of a sub 10 nm class semiconductor can occupy up to ½ of its volume, significantly reducing conductivity. Moreover, depositing the copper into such ultra-thin trench openings almost inevitably forms seams and voids that are filled with air and drastically reduce conductivity.

To avoid formation of such seams and voids, an alternative method of forming interconnections has been developed called subtractive etching, wherein a copper layer is provided first and patterned, rather than patterning a dielectric (or insulating) layer. The dielectric layer is then disposed over the patterned copper layer and its overburden is removed to expose the copper interconnections.

However, the crystalline structure of copper forms grain boundaries at the intersection of each crystal, which provide a plurality of sites to be attacked and damaged through conventional patterning processes, such as reactive ion etching or wet etching. Additionally, the grains boundaries provide a path for electro-migration and stress migration to occur, which can become an increasingly significantly issue at the 10 nm class or lower. Moreover, a barrier layer is still required to protect the dielectric (or insulating) material from damaged due to copper diffusion.

Accordingly, there is a need for a process to fabricate metal interconnections in an integrated circuit that can help avoid voids and seams in the interconnections, and reduce the need for a barrier layer between the interconnections and the insulating (or insulating) layers. Additionally, there is a need for a method of fabricating metal interconnections in an integrated circuit that can increase resistance to electro-migration and stress-migration without sacrificing conductivity.

### BRIEF DESCRIPTION

The present invention offers advantages and alternatives over the prior art by providing method of fabricating amorphous metal interconnections that avoids voids in the interconnection metal to increase conductivity. Additionally, voids are disposed in the insulating material between interconnection metal to decrease the effective dielectric constant. Moreover, the amorphous cobalt metal eliminates the need for a barrier layer between interconnection metal and dielectric (or insulator). Also the absence of grain boundaries in the amorphous metal increases resistance to electro-migration and stress-migration. Additionally, the amorphous metal will have no grain boundaries to cause non uniform attack during a metal removal process.

The method includes forming an amorphous metal layer over a base insulating layer on a semiconductor device using an amorphous metal having a non-crystalline structure. A portion of the amorphous metal layer is selectively removed to form a three dimensional pattern within a remaining portion of the amorphous metal layer. A fill insulating layer is disposed over the remaining portion of the amorphous metal layer and base insulating layer to fill the three dimensional pattern to form amorphous metal interconnects between semiconductor devices.

In some embodiments the method includes selecting the amorphous metal to have a non-crystalline structure that remains non-crystalline up to a maximum operating temperature utilized during the step of removing a portion of the amorphous metal layer.

In another aspect of the invention, the method includes the amorphous metal being substantially without grain boundaries. In other aspects the amorphous metal is neither monocrystalline nor polycrystalline.

In an alternative embodiment the method includes disposing the fill insulating layer directly over the amorphous metal layer without having a barrier layer disposed there between. In some other embodiments the method includes the fill insulating layer having air voids to reduce a dielectric constant within the openings.

### DRAWINGS

The invention will be more fully understood from the following detailed description taken in conjunction with the accompanying drawings, in which:

FIG. 1 is an exemplary embodiment of a cross-sectional view of an intermediate stage in the manufacturing of amorphous metal interconnects for an integrated circuit, wherein an amorphous metal layer is disposed on a base insulating layer and a masking layer is disposed on the amorphous metal layer in accordance with the present invention;

FIG. 2A is an exemplary embodiment of the atomic structure of an amorphous material in accordance with the present invention;

FIG. 2B is an exemplary embodiment of the atomic structure of a monocrystalline material in accordance with the present invention;

FIG. 2C is an exemplary embodiment of the atomic structure of a polycrystalline material in accordance with the present invention;

FIG. 3 is a micrograph of a polycrystalline metal in accordance with the present invention;

FIG. 4 is a graph of ratios of sheet resistance verses annealing temperatures for an amorphous cobalt alloy in accordance with the present invention; and

FIG. 5 is an exemplary embodiment of a cross-sectional view of FIG. 1 with the masking layer partially removed in accordance with the present invention;

FIG. 6 is an exemplary embodiment of a cross-sectional view of FIG. 5 with the amorphous metal layer partially removed in accordance with the present invention;

FIG. 7 is an exemplary embodiment of a cross-sectional view of FIG. 6 with the remainder of the masking layer removed in accordance with the present invention;

FIG. 8 is an exemplary embodiment of a cross-sectional view of FIG. 7 with a fill dielectric layer disposed over the amorphous metal layer in accordance with the present invention; and

FIG. 9 is an exemplary embodiment of a cross-sectional view of FIG. 8 with an overburden portion of the fill dielectric layer removed to form amorphous metal interconnects in accordance with the present invention.

### DETAILED DESCRIPTION

Certain exemplary embodiments will now be described to provide an overall understanding of the principles of the structure, function, manufacture, and use of the methods, systems, and devices disclosed herein. One or more examples of these embodiments are illustrated in the accompanying drawings. Those skilled in the art will understand that the methods, systems, and devices specifically described herein and illustrated in the accompanying drawings are non-limiting exemplary embodiments and that the scope of the present invention is defined solely by the claims. The features illustrated or described in connection with one exemplary embodiment may be combined with the features of other embodiments. Such modifications and variations are intended to be included within the scope of the present invention.

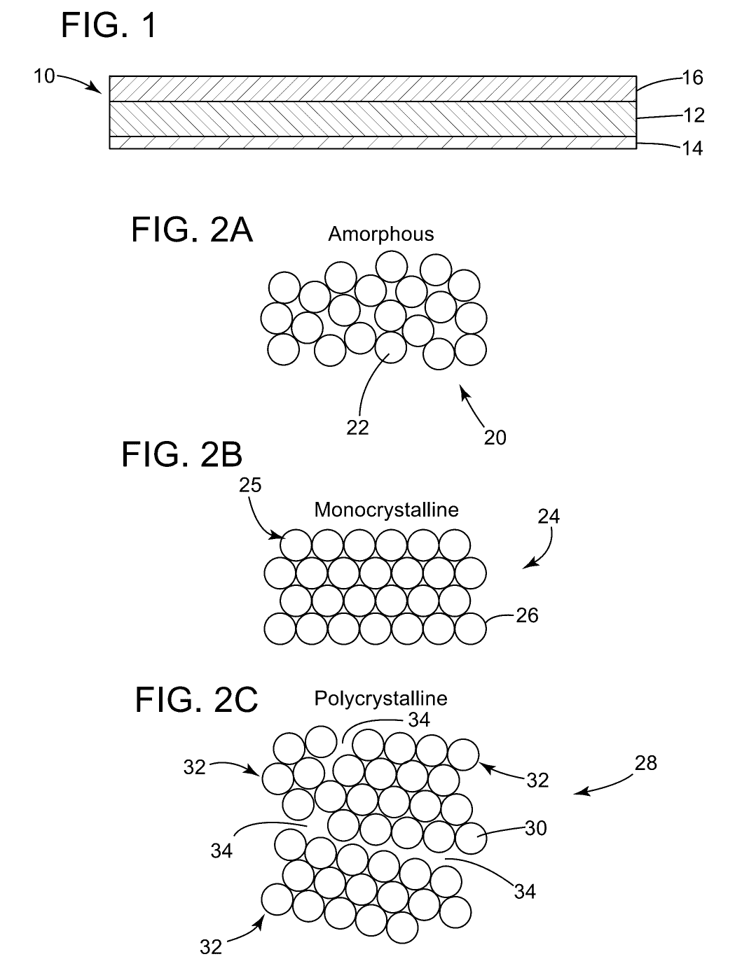

FIGS. 1-9 illustrate various exemplary embodiments of a methods of fabrication of amorphous metal interconnects for integrated circuits in accordance with the present invention.

Referring to FIG. 1, a simplified view of an exemplary embodiment of an integrated circuit device 10 having amorphous metal interconnections is shown at an intermediate stage of manufacturing. Device 10 is formed above a semiconductor substrate (not shown). The semiconductor substrate may be composed primarily of silicon. However, other commonly used materials such as carbon, germanium, gallium, boron, arsenic, nitrogen, indium, phosphorus or the like, may also be included in the composition of the semiconductor substrate.

Integrated circuit device 10 may be any type of integrated circuit device that employs any type of conductive metal structure such as conductive lines or via, commonly found in integrated circuit devices. The various components and structures of the device 10 may be initially formed using a variety of different materials and by performing a variety of known techniques.

In this particular embodiment, device 10 is in the ten nanometer (10 nm) technology class or node. As will be discussed in greater detail herein, at the 10 nm node size, the use of copper as an interconnect metal becomes increasingly problematic and challenging.

At the stage of fabrication illustrated in FIG. 1, device 10 includes an amorphous metal layer 12 disposed on a base insulating layer 14. Additionally, a masking layer 16 is disposed on the upper surface of the amorphous metal layer 12.

The base insulating layer 14 may be a blocking layer, which is used to protect underlying metal such as copper from corrosion. The insulating layer may be composed of materials such as SiN, SiCN, SiCₓN_{y}H_{z}, or the like, available under commercial names such as NBLok, NBC etc.

The amorphous metal layer 12 is composed of an amorphous metal, which may be formed over the base insulating layer using any number of well know deposition processes that coat or otherwise transfer the amorphous metal onto the base insulating layer 14 to form the amorphous metal layer 12. For example, such processes may include physical vapor deposition (PVD), chemical vapor deposition (CVD), electrochemical deposition (ECD), atomic layer deposition (ALD), electroless deposition or the like.

The metal, which composes the amorphous metal layer 12, is an amorphous metal selected to have a non-crystalline structure. An amorphous metal is a solid metallic material, usually an alloy, with a disordered atomic-scale structure. In other words, the atomic scale constituents, such as atoms, molecules and/or ions, of an amorphous metal (or any other amorphous material) is characterized by an absence of long-range order, which defines crystalline materials. Referring to FIG. 2A, an exemplary embodiment of the atomic structure of an amorphous material 20 is illustrated. In amorphous material 20, the atoms 22 are randomly ordered and have substantially no periodic arrangement (or crystal lattice), even microscopically. One such example of an amorphous material is glass and, indeed, it is said that amorphous metals exhibit a glass-like structure.

By contrast, a crystalline material is a material whose constituents, such as atoms, molecules or ions, are arranged in a highly ordered microscopic structure, which forms a crystal lattice that extends in all directions. Referring to FIG. 2B, an exemplary embodiment of the atomic structure of a crystalline material 24 is illustrated. In crystalline material 24 the atoms are in a near perfect periodic arrangement, wherein the crystal lattice 25 is unbroken throughout.

A crystalline material can be either monocrystalline or polycrystalline. If a crystalline material has a crystal lattice that is continuous and unbroken throughout the entire material from end to end, then it is monocrystalline. One such example of a monocrystalline material is the silicon substrate material typically used to fabricate semiconductors.

On the other hand, the crystal lattice on a polycrystalline material is not continuous throughout the material. Polycrystalline materials are composed of small, even microscopic, crystals of various sizes and orientations called crystallites. Crystallites are also referred to as grains. The areas where crystallite grains meet are known as grain boundaries. Referring to FIG. 2C, an exemplary embodiment of the atomic structure of a polycrystalline material 28 is illustrated. In polycrystalline material 28, the atoms are ordered in a periodic arrangement within each crystalline grain 32. However the grains 32 are randomly ordered. The areas where the grains 32 meet are the grain boundaries 34.

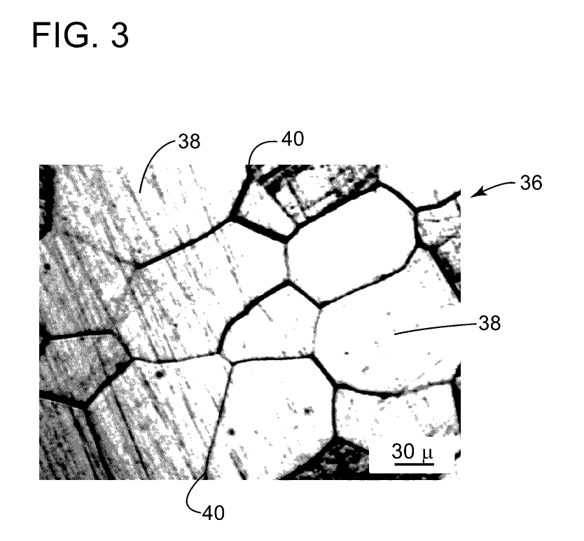

Referring to FIG. 3, a micrograph of a polycrystalline metal 36 is illustrated. Polycrystalline metal 36 has randomly ordered crystalline grains 38 that are bordered by grain boundaries 40. Almost all common metals, including copper, are polycrystalline and have grain boundaries.

The grain boundaries are defects in the crystal structure, and tend to decrease electrical and thermal conductivity. Moreover, at the 10 nm class of semiconductor fabrication, grain boundaries in polycrystalline metals, such as copper, become increasingly problematic. For example, grain boundaries provide a preferred path for electro-migration, which can eventually lead to metal contact failure. Additionally, the grain boundaries on polycrystalline copper provide sites to be attacked during various known etching processes, such as a wet etching process.

Amorphous metals, by contrast, have no grain boundaries. Amorphous metals are almost always alloys. Additionally, there are several ways in which an amorphous metal can be produced, including extremely rapid cooling, electroplating, electroless deposition, physical vapor deposition, solid-state reaction, ion irradiation and mechanical alloying.

Amorphous cobalt alloys, exhibit many attractive features as a metallic conductor, such as a metal interconnection, at sub 10 nm class scale of semiconductor fabrication. For example, an amorphous cobalt alloy will have no grain boundaries to be attacked when it is being etched during a metal removal process. Additionally, cobalt's resistivity approaches that of copper below 10 nm scale.

Moreover, with an amorphous cobalt, nickel or tungsten alloy, there is no need for a barrier layer between the metal and a dielectric (or insulator) since the cobalt, tungsten or nickel does not diffuse into and damage surrounding materials like copper does. In fact, cobalt itself is used as a barrier material for copper. Since barrier layers within patterned opening, such as trenches or via, can approach one half the volume of the opening at the 10 nm scale, then elimination of the barrier layer can significantly decrease resistivity. Known amorphous cobalt alloys include CoP, CoB, CoWP, CoWB, CoNiP, and NiCoB.

Additionally, amorphous nickel and/or amorphous nickel or tungsten alloys are also used in semiconductor fabrication and have many of the same attractive features as the cobalt alloys at the 10 nm scale. Know nickel and tungsten alloys include NiW, NiP, NiB and NiWP.

It is important to note that various amorphous metals may become polycrystalline under various elevated operating temperatures. Therefore, if the amorphous characteristics are advantageous for any given application or step of a semiconductor fabrication process, then care must be taken to select an amorphous metal that will retain its amorphous quality during the maximum operating temperatures of that given step. For example, it is important that an amorphous metal, such as a cobalt alloy, remain non-crystalline up to a maximum operating temperature of a metal removal process, such as wet or dry etching, since associated grain boundaries of a crystalline cobalt will be subject to faster attack by the etching process itself.

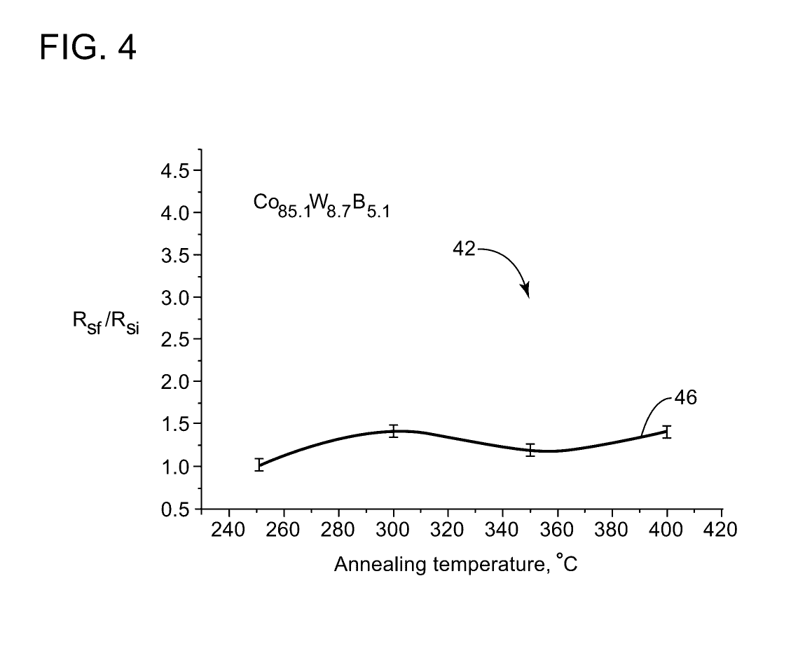

Referring to FIG. 4, a graph 42 of ratios of sheet resistance verses annealing temperatures for a cobalt alloy is illustrated. Basically the graph plots the ratios of the final sheet resistance (Rs_{f}) to the initial sheet resistance (Rsᵢ) verses operating temperatures during a two hour annealing process. The change in sheet resistance is indicative of recrystallization of the cobalt alloy. That is, if the ratio (Rs_{f}/Rsᵢ) remains close to unity, then the resistance has not changed with temperature, which indicates that the cobalt alloy has remained amorphous. If the ratio increases significantly (for example above 1.75) then the amorphous material has recrystallized. In the graph 42, it can be seen that cobalt alloy 46, which contains approximately 5 percent boron (Co_{85.2}W_{8.7}B_{5.1}), remains amorphous up to 400 degrees centigrade.

Referring again to FIG. 1, the masking layer 16 deposed over the amorphous metal layer 12 can be a hard mask material, such as SiON or TiN, used as an etch mask to pattern the underlying amorphous metal layer.

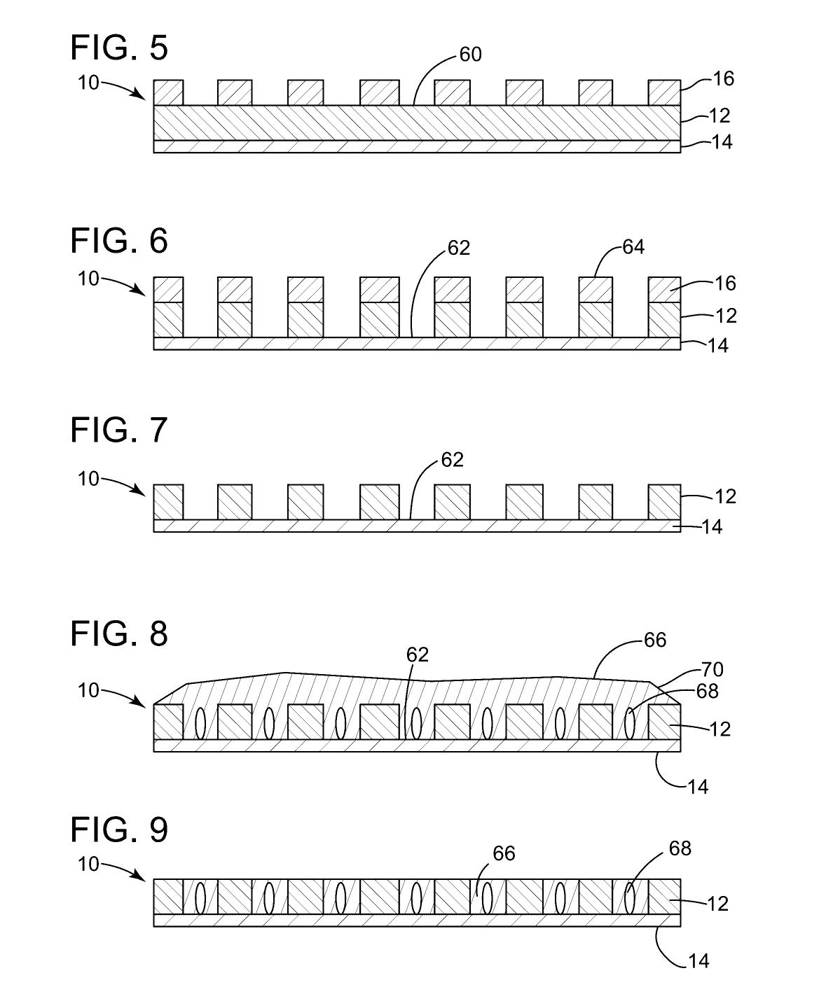

Referring to FIG. 5, a first portion of the masking layer 16 has been removed through various known patterning processes, such as lithography and etch. The removed first portion exposes a patterned surface 60 on the amorphous metal layer 12.

Referring to FIG. 6, a portion of the amorphous metal layer 12 is removed through various know etching processes such as a wet etching process, a reactive ion etching process or the like. The etching (or removal) process, removes the amorphous metal that is substantially normal to the exposed patterned surface to form a three dimensional pattern 62 within the amorphous metal layer 12.

It is important to note that since the amorphous metal layer has no crystalline structure and presents no grain boundaries for the etching process to attack, then only amorphous metal directly underlying (i.e., normal to the surface of) the exposed amorphous metal is removed. The amorphous metal layer 12 that is underneath the remaining portion 64 of masking layer 16 is not etched away.

Referring to FIG. 7, the remaining portion 64 of the masking layer 16 is removed using various known processes, such as plasma ashing, reactive ion etch, wet etch or the like. The three dimensional pattern 62 will include a plurality of openings, such as trenches and via.

Referring to FIG. 8, a fill insulating layer 66 is disposed over the amorphous metal layer 12 to fill the three dimensional pattern 62. The fill insulating layer 66 may be composed of essentially the same material as the base insulating layer 14. For example, material of the fill insulating layer 66 may be a low-k material having a dielectric constant of less than 3 and preferably as close to 1 as possible. The low-k dielectric material may be composed of materials such as SiN, SiCN, (SiCₓN_{y}H_{z}), or the like, available under commercial trade names like NBlok or NBC

Advantageously, the fill insulating layer 66 can be disposed directly over the amorphous metal layer 12 without the need for a separate barrier layer there between. This is because, unlike copper, the cobalt alloy may not diffuse into the insulating material of the fill insulating layer 66 to cause damage.

Though the exemplary embodiment of FIG. 8 is illustrating an amorphous cobalt metal layer 12 as not requiring a separate barrier layer, one skilled in the art would recognize that a polycrystalline cobalt would also advantageously not require such a barrier layer. Additionally, other polycrystalline metals can be utilized that would not diffuse into the fill insulating layer and, therefore, not require such a barrier layer. By way of example, such polycrystalline metals as cobalt, cobalt alloys, nickel, nickel alloys, tungsten and tungsten alloys can be used as the metal layer 12 and not require a barrier layer disposed between the metal layer 12 and the fill insulating layer 66.

However, the feature of having no grain boundaries, and the advantages that are associated with it, are only possible if the metal layer 12 is an amorphous metal layer. Such added advantages of an amorphous metal layer 12 would include no grain boundaries to provide sites to be attacked during various known etching processes and an added resistance to electro-migration.

Because of the extremely short distances between the patterned openings within the amorphous metal layer 12, the fill insulating layer will more than likely have voids 68 disposed within the openings of the three dimensional pattern 62. However, these voids 68 (or air gaps) are advantageous and desirable. This is because air has a dielectric constant of 1, which reduces the overall effective dielectric constant of the insulating material within the opens.

The fill insulating layer 66 includes an overburden portion 70 which extends above the surface of the amorphous metal layer 12. That overburden portion 70 can be removed as illustrated in FIG. 9 through various know processes, such as chemical mechanical polishing, to complete the method of fabrication of amorphous metal interconnects.

Unlike previous methods, the amorphous metal interconnects of the present invention will not have voids or air gaps which undesirably reduce conductivity. Additionally, there will be voids in the insulating material between the interconnects where they will advantageously reduce the overall dielectric constant.

Moreover, because the interconnect material is amorphous and has no grain boundaries, there is an increased resistance to electro-migration and stress-migration. Moreover, absence of grain boundaries meant that the etching process utilized in forming the three dimensional pattern did little or no damage to the amorphous metal directly under the protective hard mask. Also, because the metal is preferably a cobalt alloy, there is no need for a barrier layer between the fill insulating material and the amorphous metal of the interconnects.

Although the invention has been described by reference to specific embodiments, it should be understood that numerous changes may be made within the spirit and scope of the inventive concepts described. Accordingly, it is intended that the invention not be limited to the described embodiments, but that it have the full scope defined by the language of the following claims.

1. A method comprising:
forming an amorphous metal layer over a base insulating layer on a semiconductor device using an amorphous metal having a non-crystalline structure;
selectively etching a portion of the amorphous metal layer to form a three dimensional pattern within a remaining portion of the amorphous metal layer, the pattern including exposed portions of the base insulating layer as bottom surfaces of the pattern; and
disposing a fill insulating layer over the remaining portion of the amorphous metal layer and base insulating layer to fill the three dimensional pattern to form amorphous metal interconnects between semiconductor devices.

2. The method of claim 1 comprising selecting the amorphous metal to have a non-crystalline structure that remains non-crystalline up to a maximum operating temperature utilized during the step of etching a portion of the amorphous metal layer.

3. The method of claim 2 wherein the maximum operating temperature is 400 degrees centigrade.

4. The method of claim 1 wherein the amorphous metal is substantially without grain boundaries.

5. The method of claim 1 wherein the amorphous metal is neither monocrystalline nor polycrystalline.

6. The method of claim 1 wherein the amorphous metal is an alloy.

7. The method of claim 6 wherein the amorphous metal is one of an alloy of cobalt, an alloy of nickel and an alloy of tungsten.

8. The method of claim 6 wherein the amorphous metal is one of a group of amorphous metals, the group including CoP, CoB, NiW, CoWP, CoWB, CoNiP, NiP, NiB, NiCoB and NiWP.

9. The method of claim 1 wherein the three dimensional pattern includes a plurality of openings that are substantially without grain boundaries.

10. The method of claim 9 wherein the openings include a plurality of trenches and via.

11. The method of claim 1 comprising disposing the fill insulating layer directly over the amorphous metal layer without having a barrier layer disposed there between.

12. The method of claim 1 wherein the fill insulating layer is composed of a low dielectric constant material having a dielectric constant of less than 3.

13. The method of claim 1 wherein the fill insulating layer includes air voids to reduce a dielectric constant within the openings.

14. The method of claim 1 comprising removing an overburden portion of the fill insulating layer to expose the patterned surface of the amorphous metal layer.

15. A metal interconnection for a semiconductor device, the interconnection comprising:
a base insulating layer;
an amorphous metal layer disposed on the base insulating layer, the amorphous metal layer composed of an amorphous metal having an non-crystalline structure;
a three dimensional pattern formed within a portion of the amorphous metal layer; and
a fill insulating layer disposed over the amorphous metal layer and base insulating layer to fill the three dimensional pattern to form an amorphous metal interconnect.

16. The metal interconnection of claim 15 wherein the amorphous metal is substantially without grain boundaries.

17. The metal interconnection of claim 15 wherein the amorphous metal has a non-crystalline structure that remains non-crystalline up to a maximum operating temperature utilized during a metal removal step in fabrication of the metal interconnection.

18-20. (canceled)

21. The method of claim 1 comprising selecting the amorphous metal to have a ratio of a final sheet resistance taken at the end of a two hour annealing process to an initial sheet resistance taken at the beginning of the two hour annealing process of 1.75 or less.

22. The method of claim 21 wherein the two hour annealing process subjected the amorphous metal to temperatures up to 400 degrees centigrade.

23. The method of claim 21 wherein the amorphous metal is a cobalt alloy.
